(19) United States
(12) Patent Application Publication
(10) Pub. No.: US 2008/0071488 A1
(43) Pub. Date: Mar. 20, 2008

(54) Method and apparatus for evaluating data

(75) Inventors: Anthony Cake, Givrins (CH); Yann Oeffner, La Rippe (CH)

Correspondence Address: LECROY CORPORATION, 700 CHESTNUT RIDGE ROAD, CHESTNUT RIDGE, NY, 10977, US

(73) Assignee: LeCroy Corporation, Chestnut Ridge, NY (US)

(21) Appl. No.: 11/893,179

(22) Filed: Aug. 15, 2007

Related U.S. Application Data
(60) Provisional application No. 60/838,489, filed on Aug. 17, 2006.

(51) Int. Cl. G01R 13/02; G06F 19/00

(52) U.S. Cl. 702/67; 702/70

(57) ABSTRACT

A method and apparatus for evaluating data are provided. The method comprises the steps of acquiring waveform data, performing one or more measurements on the waveform data to generate measurement data, applying a filter to the generated measurement data and generating a histogram in accordance with the filtered measurement data. One or more rarest values from the histogram are designated in accordance with the filtered measurement data, and an additional filter is generated in accordance with the one or more designated rarest values. The additional filter is applied to the generated measurement data.

### CROSS REFERENCE TO RELATED APPLICATIONS

This application claims the benefit of U.S. Provisional Patent Application Ser. No. 60/838,489, filed Aug. 17, 2006, entitled “METHOD AND APPARATUS FOR EVALUATING DATA”, currently pending, the contents thereof being incorporated herein by reference.

### BACKGROUND OF THE INVENTION

When using an oscilloscope or other test and measurement device to view captured data, the user may be interested in many different types of analysis. When that user is looking for rare and possibly erroneous conditions via a histogram or other appropriate data display, data that is likely to be the most interesting for the user is often found in the outliers of such a histogram, indicating a substantial deviation from the most normal or average captured data. Using traditional histogramming of measurement values in a digital oscilloscope or other appropriate test and measurement device allows these rare occurrences (outliers) to be viewed. However, the waveforms, which when measured generated these outliers, are not easy to view as there is normally no maintenance of any connection between the original waveforms and the histogrammed data. This situation is even more pronounced when using a persistence display consisting of data accumulated from multiple data acquisitions. In such a digital oscilloscope, sometimes even many hundreds or thousands of multiple waveforms may be overlaid on the display to form the persistence display. Any one or more of these waveforms may include the waveforms that generated the histogram outliers. However, there is currently no easy way to relate an outlier or a cluster of outliers in a histogram to the waveform(s) from which they were generated.

### SUMMARY OF THE INVENTION

In accordance with the invention, a method and apparatus are provided for allowing a user to select an outlier, or group of outliers, of interest in a particular screen rendering of a measured characteristic of one or more input waveforms or waveform segments. Such selection is preferably made by individually selecting a particular data point or alternatively dragging a rectangle or other indicator around the desired data points using a mouse, touch screen or other input device. However, any appropriate selection mechanism may be employed. The desired outliers may also be selected in accordance with a predetermined algorithm provided by the oscilloscope or other test and measurement apparatus. The invention then shows to the user the waveforms (or waveform segments) that generated the selected outliers. In addition, waveforms on a channel of the oscilloscope other than that on which the waveform was acquired that might have provoked the erroneous condition may similarly be viewed. As an example, a sagging power supply may cause errors in digital logic designs, and would be accessible in accordance with the invention.

Therefore it is an object of the invention to provide a user with an improved tool for evaluating data.

Still other objects and advantages of the invention will in part be obvious and will in part be apparent from the specification and the drawings.

The invention accordingly comprises the several steps and the relation of one or more of such steps with respect to each of the others, and the apparatus embodying features of construction, combination(s) of elements and arrangement of parts that are adapted to effect such steps, all as exemplified in the following detailed disclosure, and the scope of the invention will be indicated in the claims.

### DESCRIPTION OF THE DRAWINGS

For a more complete understanding of the invention, reference is made to the following description and accompanying drawings, in which:

FIG. 1 is a flow chart diagram depicting conventional processing of data in a digital oscilloscope;

FIG. 2 is a flowchart diagram depicting processing of data in a digital oscilloscope in accordance with an embodiment of the invention;

FIG. 3 shows a histogram depicting an expected Gaussian distribution of measured pulse widths, plus some outliers in accordance with the invention;

FIG. 4 shows a number of actual measured pulse widths making up an input waveform in accordance with the invention;

FIG. 5 shows selection of a number of outliers in accordance with the invention;

FIG. 6 shoes programming of pulse width limits for the measurement filter in accordance with the invention;

FIG. 7 is a flowchart diagram depicting processing of data in a digital oscilloscope in accordance with an additional embodiment of the invention;

FIG. 8 is shows designation of events which pass filter limits in accordance with the invention;

FIG. 9 depicts one of the designated events of FIG. 8 in accordance with the invention;

FIG. 10 depicts a dialog to quickly page through designated portions of an acquired waveform in accordance with the invention;

FIG. 11 shows a number of views of two rarest events of a waveform in accordance with the invention; and

FIG. 12 depicts the location of the two rarest events of FIG. 11 in a histogram.

### DETAILED DESCRIPTION OF THE INVENTION

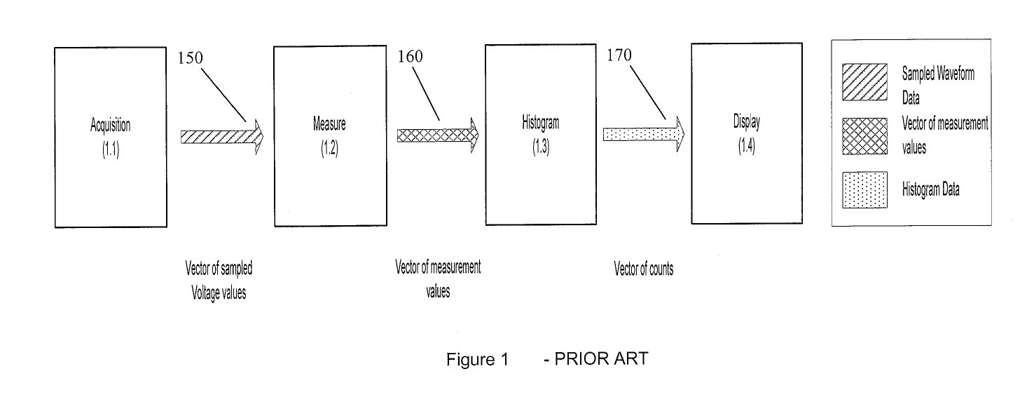

The invention will now be described making reference to the drawings. FIG. 1 depicts a block diagram of the processing flow in a conventional digital oscilloscope during a normal progression of processing of incoming data. The processing flow includes acquisition of input data, measurement of the acquired data, histogram generation based upon the measured acquired data, and rendering of the histogram on a display. In this typical processing flow, data is acquired by an acquisition system at block (1.1) and data values 150 of the acquired data are processed to generate zero or more measurements 160 at block (1.2). These measurements 160 may be binned into a histogram 170 at block (1.3), and finally histogram 170 is rendered onto a display at block (1.4).

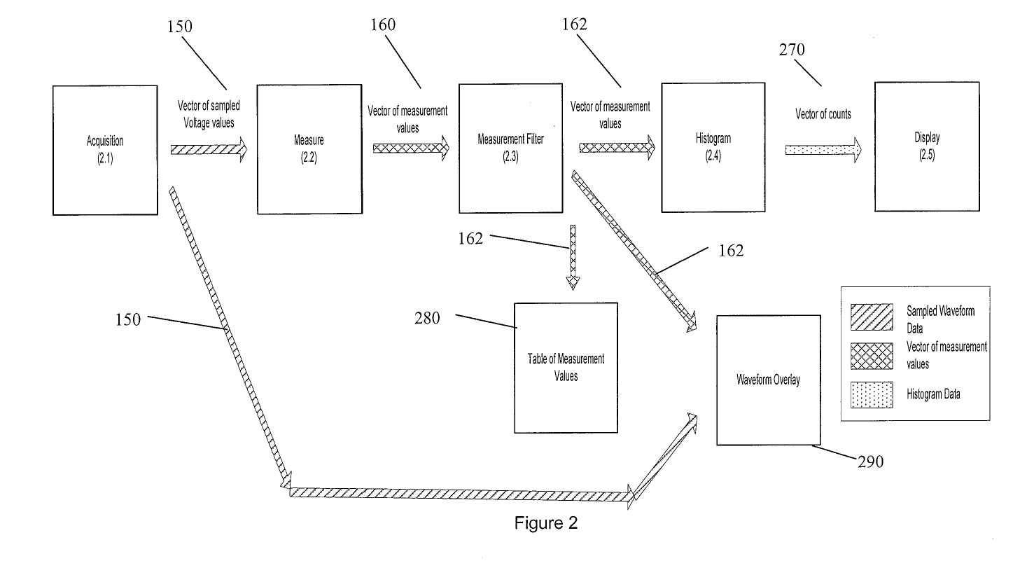

In accordance with the invention, FIG. 2 depicts a modified block diagram including various changes employed to implement the invention in accordance with a preferred embodiment. Other sequences of processing may also be appropriate. In accordance with this preferred embodiment of the invention, data is acquired at block (2.1) and data values 150 of the acquired data are processed to generate zero or more measurements 160 at block (2.2), as noted above. At this point in accordance with the preferred embodiment of the invention, a filter is applied at block (2.3) which passes only a subset of the measurement values 162 on to the histogrammer in block (2.4). This filter may implement any of several common filtering techniques, for example, values less than a threshold (<), values greater than a threshold (>), values within a predetermined range, values outside of a predetermined range, etc. Once the filtered set of values 162 has been histogrammed at block (2.4) to generate a histogram 270, the histogram may be rendered onto the display at block (2.5) as noted above. Only measurements which pass the filter at block (2.3) are used in histogram 270. Filtered measurement values 162 may optionally be presented to the user in tabular form (Table of Measurement Values) 280, or used to overlay the measured waveform segments into a form of persistence map (Waveform Overlay) 290.

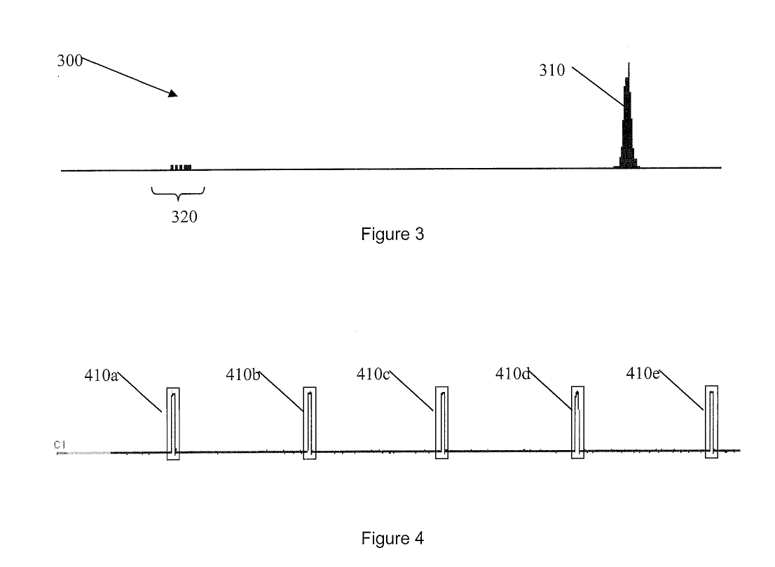

The various data input and output values will now be described. First a histogram is generated of (in this case) a measurement of various Pulse widths of the pulses of an input signal. Such a histogram is shown in FIG. 3, depicting an expected Gaussian distribution of measured pulse widths 310 (right), plus some outliers 320 (left). With no filtering (yet), all of the actual measured pulse widths making up the input waveform are highlighted (or otherwise indicated as being included in the data that make up the histogram), as shown in FIG. 4. Thus, each measured pulse width 410a, 410b, 410c, 410d and 410e is shown as selected, or not excluded, and thus is included in the histogram.

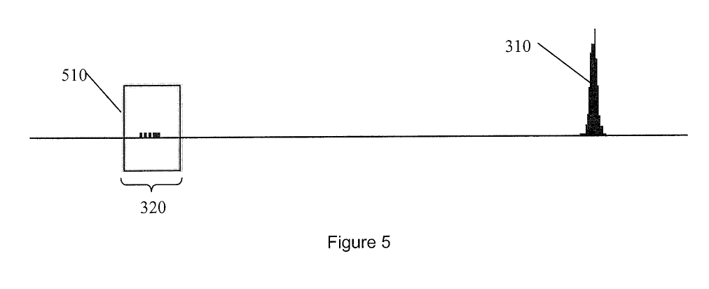

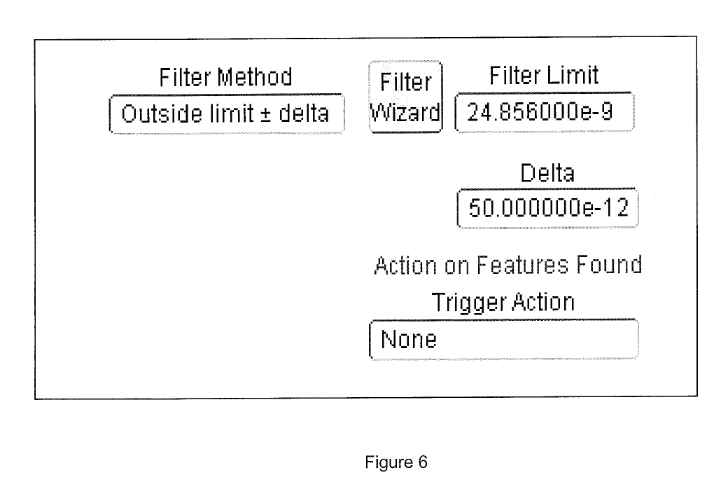

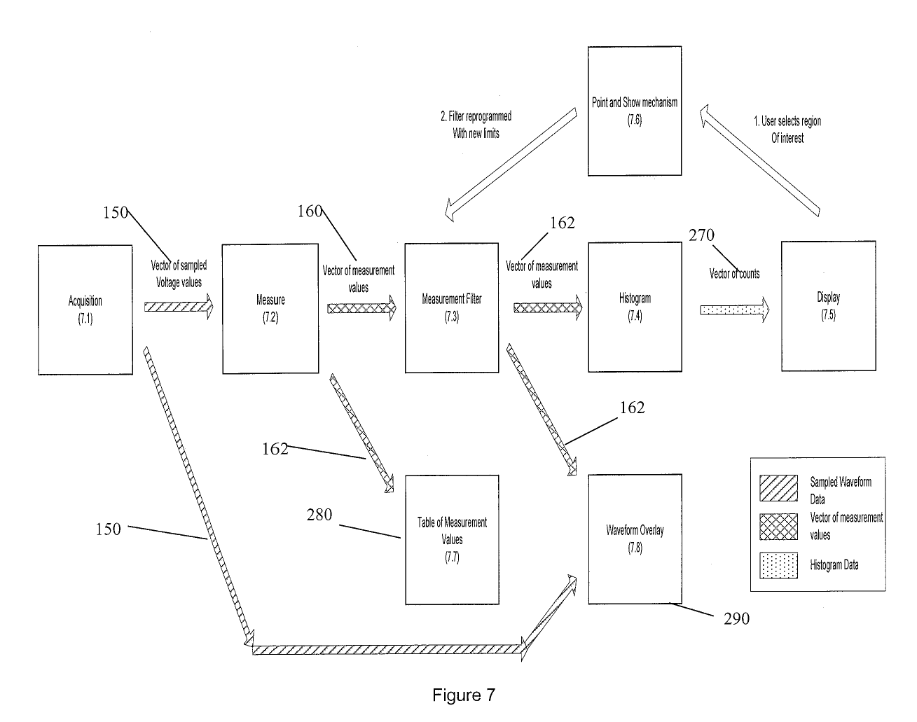

In accordance with the invention, a user is able to select one or more outliers 320, by dragging a rectangle 510 or other selection mechanism over them, or by selecting a particular outlier, as shown in FIG. 5. Based upon the horizontal extremes of the dragged rectangle indicator 510, the measurement filter is programmed to accept only measurements of pulse width within these limits, as is shown in FIG. 6, and according to the block diagram of FIG. 7.

In accordance with this preferred embodiment of the invention, data is acquired at block (7.1) and data values 150 of the acquired data are processed to generate zero or more measurements 160 at block (7.2), as noted above. At this point in accordance with the preferred embodiment of the invention, a filter is applied at block (7.3) which passes only a subset of the measurement values 162 on to the histogrammer in block (7.4). This filter may implement any of several common filtering techniques, for example, values less than a threshold (<), values greater than a threshold (>), values within a predetermined range, values outside of a predetermined range, etc. Once the filtered set of values 162 has been histogrammed at block (7.4) to generate a histogram 270, the histogram may be rendered onto the display at block (7.5). Only measurements which pass the filter at block (7.3) are used in histogram 270. Filtered measurement values 162 may optionally be presented to the user in tabular form (Table of Measurement Values) 280, or used to overlay the measured waveform segments into a form of persistence map (Waveform Overlay) 290. A user may then select a region of interest, as noted above, by either dragging a rectangle or other selection indicator over part of the rendition of the histogram, or simply by selecting a portion of the histogram by other means at block (7.6). This action causes a filter configuration to be created, and programmed into the measurement filter employed at block (7.3).

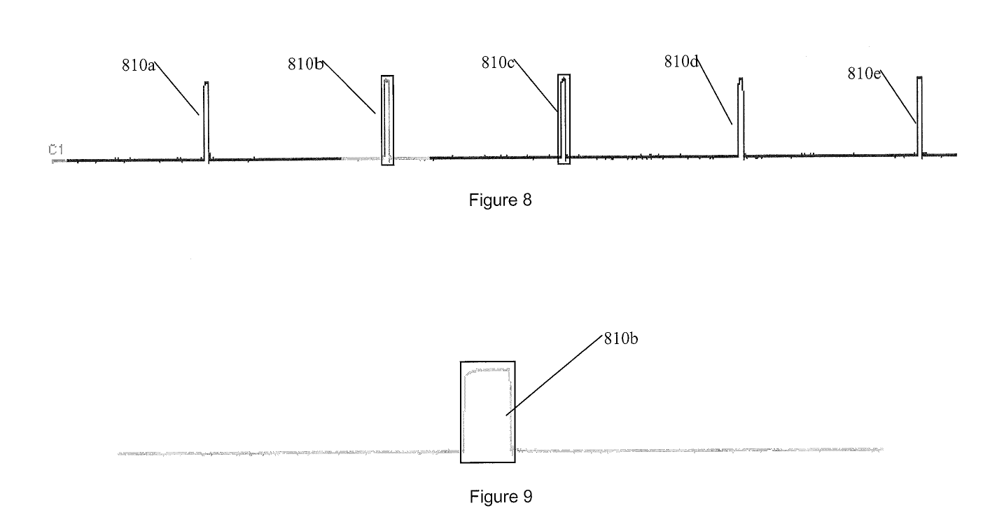

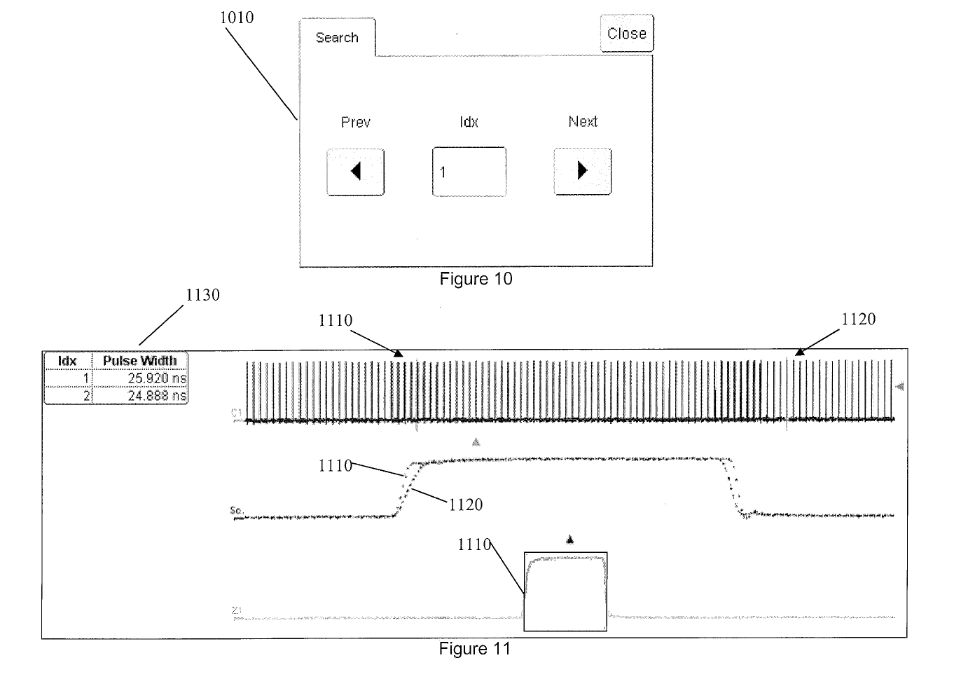

After this modified filter is applied at block (7.3), and appropriate filtering takes place on the measured values 160, the trace now only highlights or otherwise designates the events which pass these designated filter limits, as shown in FIG. 8 (810b, 810c), (810a, 810d, 810e not being associated with the selected portions of the histogram. Thus, only the actual portions of the input acquired signal that generated the histogram entries included within the selected portion of the histogram are designated in the waveform. While highlighting is preferably used, any designation of the portions of the waveform is appropriate. Once the appropriate portions of the trace are designated, the user can easily view, and zoom in on, selected events from the acquired waveform that pass the limits noted in the above steps, as shown in FIG. 9. A menu selection 1010, such as that shown in FIG. 10 allows a user to easily page from one designated event to another, or jump directly to a desired value. Furthermore, if no visible indication of inclusion of a particular waveform segment in the selected histogram values is employed (i.e. no highlighting), a user may still be able to use the dialog box of FIG. 10 to quickly page through the designated portions of the acquired waveform.

Other related uses of the invention include jumping between other waveform domains. For example, a user might click on an area within a measurement trend that has an event count as its X axis, and a measurement value as its Y axis. The user may then draw a rectangle or otherwise designate a region of interest. In this case the user may use the vertical extents of the rectangle to determine limits to program into a filter. Indeed, any situation in which physical limits of a designated portion of a measurement are used to generate filter instructions is contemplated as being part of the invention.

While the above invention has been described as applicable to a trend feature (one in which events are grouped by measured values, such as a histogram) it is equally applicable to use in conjunction with a track feature (one in which events are placed in time based upon where they occurred in the source waveform, rather than being grouped by measured value). Other similar uses of the invention are intended to be included in this description.

In accordance with an additional embodiment of the invention, it is contemplated to define the events one wishes to view as those that occur least often, or are the rarest. In the context of this invention, when scanning a waveform for a rare (and possibly erroneous) event, it makes sense to sort events in order of rarity. In the simplest case, this can mean looking at the histogram of a measurement value, and presenting the user with events from the left, and right, extremes, without the requirement of selection by the user. In the case of a pulse width, as used in the example above, this would return the widest, and narrowest measured pulses. Applied to rise time, this feature would return the slowest and fastest rise times (of which the slowest is generally the most interesting). Unlike the filtering by numeric value shown in the previous example, this rarest feature (assuming sufficient events in the waveform being measured) would always find events of interest as there is always a rarest event.

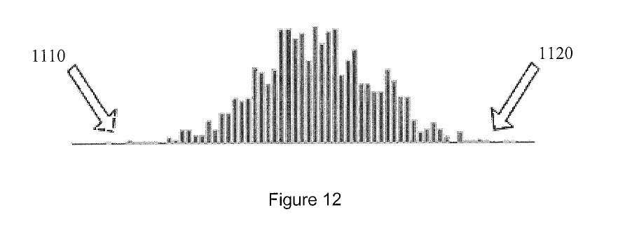

The first portion of the example of FIG. 11 shows the 2 rarest events (indicated by arrows A), including the narrowest and widest width. These values are highlighted, but may be designated in any manner. The second portion of FIG. 11 shows the two actual waveform segments 1110, 1120 from which these two measurements were taken overlaid in a persistence map, generated by, for example, block (7.8) in FIG. 7. The third portion of FIG. 11 shows a single one of these events zoomed in on by a user. Also shown in FIG. 11 are the measurement values in table form 1130, generated by block (7.7) in FIG. 7. The location of these measurements in an associated histogram is indicated by arrows (1110, 1120) in FIG. 12.

It will thus be seen that the objects set forth above, among those made apparent from the preceding description, are efficiently attained and, because certain changes may be made in carrying out the above method and in the construction(s) set forth without departing from the spirit and scope of the invention, it is intended that all matter contained in the above description and shown in the accompanying drawings shall be interpreted as illustrative and not in a limiting sense.

It is also to be understood that the description is intended to cover all of the generic and specific features of the invention herein described and all statements of the scope of the invention which, as a matter of language, might be said to fall there between.

What is claimed:

1. A method for evaluating data, comprising the steps of:
acquiring waveform data;
performing one or more measurements on the waveform data to generate measurement data;
applying a filter to the generated measurement data; and
generating a histogram in accordance with the filtered measurement data.

2. The method of claim 1, further comprising the step of displaying the filtered measurement data.

3. The method of claim 1, further comprising the step of generating a table of the filtered measurement data.

4. The method of claim 1, further comprising the step of displaying overlaid waveform data in accordance with the filtered measurement data.

5. The method of claim 1, further comprising the step of designating one or more values comprising the histogram in accordance with the filtered measurement data.

6. The method of claim 5, wherein the designating is performed by a user.

7. Then method of claim 5, wherein the designating is performed in accordance with a predefined algorithm.

8. The method of claim 7, wherein the predefined algorithm determines at least a rarest event.

9. The method of claim 5, further comprising the step of generating an additional filter in accordance with the one or more designated values.

10. The method according to claim 9, wherein the step of applying the filter to the generated measurement data is performed again in accordance with the additional filter.

11. An apparatus for evaluating data, comprising:
an acquisition system for acquiring data;
a controller for performing one or more measurements on the waveform data to generate measurement data, applying a filter to the generated measurement data, and generating a histogram in accordance with the filtered measurement data.

12. The apparatus of claim 11, further comprising a display for displaying the filtered measurement data.

13. The apparatus of claim 12, wherein the display further displays overlaid waveform data.

14. The apparatus of claim 11, wherein the controller further generates a table of the filtered measurement data.

15. The apparatus of claim 11, further comprising a selector for designating one or more values comprising the histogram in accordance with the filtered measurement data.

16. The apparatus of claim 15, where the selector is operated by a user.

17. The apparatus of claim 15, wherein the selector is operated by the controller in accordance with a predefined algorithm.

18. The apparatus of claim 17, wherein the controller determined at least a rarest even in accordance with the predefined algorithm.

19. The apparatus of claim 15, wherein the controller further generates an additional filter in accordance with the designated one or more values and applies the additional filter to the generated measurement data.

20. A method for evaluating data, comprising the steps of:
acquiring waveform data;
performing one or more measurements on the waveform data to generate measurement data;
applying a filter to the generated measurement data;
generating a histogram in accordance with the filtered measurement data;
designating one or more rarest values comprising the histogram in accordance with the filtered measurement data;
generating an additional filter in accordance with the one or more designated rarest values; and
applying the additional filter to the generated measurement data.
